(19) United States
(12) Patent Application Publication
(10) Pub. No.: US 2026/0130131 A1
(43) Pub. Date: May 7, 2026

(54) SELF-HEALING FERROELECTRIC CAPACITORS WITH ENDURANCE IMPROVEMENT AT HIGH TEMPERATURES

(71) Applicant: Georgia Tech Research Corporation, Atlanta, GA (US)

(72) Inventors: Nashrah Afroze, Atlanta, GA (US); Asif Islam Khan, Atlanta, GA (US); Prasanna Venkatesan Ravindran, Atlanta, GA (US); Yu Hsin Kuo, Atlanta, GA (US); Janak Sharda, Atlanta, GA (US); Shimeng Yu, Atlanta, GA (US); Eknath Sarkar, Atlanta, GA (US); Suman Datta, Atlanta, GA (US); Salma Soliman, Atlanta, GA (US)

(21) Appl. No.: 19/381,890

(22) Filed: Nov. 6, 2025

Related U.S. Application Data
(60) Provisional application No. 63/717,716, filed on Nov. 7, 2024.

(51) Int. Cl. H10N 70/20; H10D 1/68; H10N 70/00

(52) U.S. Cl. CPC H10N 70/24; H10N 70/028; H10N 70/8833; H10D 1/68

(57) ABSTRACT

The present disclosure provides a ferroelectric device comprising first and second electrodes with a ferroelectric layer disposed between them. The ferroelectric layer comprises a hafnium-based oxide. An oxygen reservoir layer is disposed at an interface between one electrode and the ferroelectric layer, configured to supply oxygen ions during operation. The hafnium-based oxide may comprise hafnium zirconium oxide having composition Hf_{0.5}Zr_{0.5}O₂. The oxygen reservoir layer may comprise tungsten oxide having formula WOₓ, where x is less than 3, with thickness ranging 4-6 nanometers. The device may further comprise a second oxygen reservoir layer at the interface between the second electrode and ferroelectric layer to provide bidirectional oxygen ion supply during bipolar cycling operation.

### CROSS-REFERENCE TO RELATED APPLICATIONS

This application claims priority to U.S. Provisional Application No. 63/717,716, filed on 7 Nov. 2024, which is hereby incorporated by reference in its entirety.

### FIELD OF INVENTION

The present disclosure relates to ferroelectric memory devices, and more particularly to ferroelectric capacitors with oxygen reservoir layers for improved endurance performance at elevated temperatures.

### BACKGROUND

Ferroelectric memory devices have emerged as promising candidates for next-generation non-volatile memory applications due to their fast switching speeds, low power consumption, and compatibility with complementary metal-oxide-semiconductor (CMOS) fabrication processes. These devices utilize ferroelectric materials that exhibit spontaneous electric polarization that can be reversed by applying an external electric field, enabling data storage through polarization states.

Hafnium-based ferroelectric materials, particularly hafnium zirconium oxide (HZO), have gained attention in the semiconductor industry for their scalability to nanometer dimensions and integration compatibility with existing silicon technology. These materials can maintain ferroelectric properties in ultrathin films, making them suitable for high-density memory applications and three-dimensional integrated circuits.

However, ferroelectric memory devices face reliability challenges that limit their widespread adoption. During operation, these devices experience degradation mechanisms that affect their performance and operational lifetime. One such mechanism involves the formation and migration of oxygen vacancies within the ferroelectric material during repeated switching cycles. These defects can accumulate over time and create conductive pathways that compromise the insulating properties of the ferroelectric layer.

The reliability challenges become more pronounced at elevated temperatures, which are encountered in various applications including three-dimensional memory architectures where heat dissipation is limited, and in systems where ferroelectric memories are integrated with heat-generating logic circuits. At higher operating temperatures, the degradation processes accelerate, leading to reduced endurance and shorter device lifetimes.

Current approaches to address these reliability issues include material engineering, interface optimization, and process modifications. However, there remains a need for improved ferroelectric device structures that can maintain reliable operation across a wide temperature range while preserving the advantageous properties of ferroelectric materials for memory applications.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an aspect of the present disclosure, a ferroelectric device is provided. The ferroelectric device includes a first electrode and a second electrode. The ferroelectric device includes a ferroelectric layer disposed between the first electrode and the second electrode, the ferroelectric layer comprising a hafnium-based oxide. The ferroelectric device includes an oxygen reservoir layer disposed at an interface between one of the first electrode or the second electrode and the ferroelectric layer, the oxygen reservoir layer configured to supply oxygen ions to the ferroelectric layer during operation of the ferroelectric device.

According to other aspects of the present disclosure, the ferroelectric device may include one or more of the following features. The hafnium-based oxide may comprise hafnium zirconium oxide (HZO). The oxygen reservoir layer may comprise tungsten and oxygen and hafnium zirconium oxide may have a composition of Hf_{0.5}Zr_{0.5}O₂. The oxygen reservoir layer may have a thickness in a range of 4 nanometers to 6 nanometers. The ferroelectric layer may have a thickness of about 5 nanometers. The oxygen reservoir layer may comprise tungsten oxide having the formula WOₓ, where x is less than 3. The oxygen reservoir layer may be sub-stoichiometric and may comprise oxygen vacancies. The oxygen reservoir layer may be disposed at an interface between the first electrode and the ferroelectric layer. The ferroelectric device may further comprise a second oxygen reservoir layer disposed at an interface between the second electrode and the ferroelectric layer. The oxygen reservoir layer and the second oxygen reservoir layer may be configured to provide bidirectional oxygen ion supply to the ferroelectric layer during bipolar cycling operation.

According to another aspect of the present disclosure, a method of fabricating a ferroelectric device is provided. The method comprises depositing a first electrode. The method comprises depositing an oxygen reservoir layer on the first electrode. The method comprises depositing a ferroelectric layer comprising a hafnium-based oxide on the oxygen reservoir layer. The method comprises depositing a second electrode on the ferroelectric layer. The oxygen reservoir layer is configured to supply oxygen ions to the ferroelectric layer during operation of the ferroelectric device.

According to other aspects of the present disclosure, the method may include one or more of the following features. Depositing the oxygen reservoir layer may comprise depositing tungsten oxide having the formula WOₓ, where x is less than 3. Depositing the oxygen reservoir layer may comprise depositing tungsten as the first electrode and applying oxygen plasma to the tungsten to form the oxygen reservoir layer. Depositing the oxygen reservoir layer may comprise atomic layer deposition of tungsten oxide. The atomic layer deposition may be performed at a temperature of about 250° C.

According to another aspect of the present disclosure, a ferroelectric capacitor is provided. The ferroelectric capacitor comprises a bottom electrode comprising tungsten and a top electrode. The ferroelectric capacitor comprises a ferroelectric layer disposed between the bottom electrode and the top electrode, the ferroelectric layer comprising hafnium zirconium oxide. The ferroelectric capacitor comprises a first oxygen reservoir layer disposed between the bottom electrode and the ferroelectric layer and a second oxygen reservoir layer disposed between the ferroelectric layer and the top electrode. Each of the first oxygen reservoir layer and the second oxygen reservoir layer comprises tungsten oxide and is configured to reduce oxygen vacancy formation in the ferroelectric layer during cycling operations.

According to other aspects of the present disclosure, the ferroelectric capacitor may include one or more of the following features. The hafnium zirconium oxide may have a composition of Hf_{0.5}Zr_{0.5}O₂. Each of the first oxygen reservoir layer and the second oxygen reservoir layer may have a thickness in a range of 4 nanometers to 6 nanometers. The ferroelectric layer may have a thickness of about 5 nanometers. Each of the first oxygen reservoir layer and the second oxygen reservoir layer may comprise tungsten oxide having the formula WOₓ, where x is less than 3, and the tungsten oxide may be sub-stoichiometric and may comprise oxygen vacancies.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF FIGURES

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIG. 1A illustrates a schematic cross-sectional view of a conventional ferroelectric device structure, according to aspects of the present disclosure.

FIG. 1B illustrates a cross-sectional image of the conventional ferroelectric device of FIG. 1A, according to aspects of the present disclosure.

FIG. 1C illustrates oxygen vacancy formation in the ferroelectric device of FIG. 1A during cycling operations, according to aspects of the present disclosure.

FIG. 2A illustrates a schematic cross-sectional view of a ferroelectric device with an upper oxygen reservoir layer, according to aspects of the present disclosure.

FIG. 2B illustrates a cross-sectional image of the ferroelectric device of FIG. 2A, according to aspects of the present disclosure.

FIG. 2C illustrates oxygen ion supply from the upper oxygen reservoir layer to the ferroelectric layer of FIG. 2A, according to aspects of the present disclosure.

FIG. 3A illustrates a schematic cross-sectional view of a ferroelectric device with a lower oxygen reservoir layer, according to aspects of the present disclosure.

FIG. 3B illustrates a cross-sectional image of the ferroelectric device of FIG. 3A, according to aspects of the present disclosure.

FIG. 3C illustrates oxygen ion supply from the lower oxygen reservoir layer to the ferroelectric layer of FIG. 3A, according to aspects of the present disclosure.

FIG. 4A illustrates a schematic cross-sectional view of a ferroelectric device with dual oxygen reservoir layers, according to aspects of the present disclosure.

FIG. 4B illustrates a cross-sectional image of the ferroelectric device of FIG. 4A, according to aspects of the present disclosure.

FIG. 4C illustrates bidirectional oxygen ion supply from the dual oxygen reservoir layers of FIG. 4A, according to aspects of the present disclosure.

FIGS. 5A-5D illustrate endurance data comparing reference and oxygen reservoir layer devices at different temperatures, according to aspects of the present disclosure.

FIG. 6 illustrates trap generation rate versus cycling data for ferroelectric capacitors at different temperatures, according to aspects of the present disclosure.

### DETAILED DESCRIPTION

Although preferred exemplary embodiments of the disclosure are explained in detail, it is to be understood that other exemplary embodiments are contemplated. Accordingly, it is not intended that the disclosure is limited in its scope to the details of construction and arrangement of components set forth in the following description or illustrated in the drawings. The disclosure is capable of other exemplary embodiments and of being practiced or carried out in various ways. Also, in describing the preferred exemplary embodiments, specific terminology will be resorted to for the sake of clarity.

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include, but are not limited to, similar components or steps that are developed after development of the embodiments disclosed herein.

As used in the specification and the appended claims, the singular forms “a,” “an” and “the” include plural referents unless the context clearly dictates otherwise.

Also, in describing the preferred exemplary embodiments, terminology will be resorted to for the sake of clarity. It is intended that each term contemplates its broadest meaning as understood by those skilled in the art and includes all technical equivalents which operate in a similar manner to accomplish a similar purpose.

Ranges can be expressed herein as from “about” or “approximately” one particular value and/or to “about” or “approximately” another particular value. When such a range is expressed, another exemplary embodiment includes from the one particular value and/or to the other particular value.

Similarly, as used herein, “substantially free” of something, or “substantially pure”, and like characterizations, can include both being “at least substantially free” of something, or “at least substantially pure”, and being “completely free” of something, or “completely pure”.

By “comprising” or “containing” or “including” is meant that at least the named compound, member, particle, or method step is present in the composition or article or method, but does not exclude the presence of other compounds, materials, particles, method steps, even if the other such compounds, material, particles, method steps have the same function as what is named.

Mention of one or more method steps does not preclude the presence of additional method steps or intervening method steps between those steps expressly identified. Similarly, it is also to be understood that the mention of one or more components in a device or system does not preclude the presence of additional components or intervening components between those components expressly identified.

The materials described as making up the various members of the invention are intended to be illustrative and not restrictive. Many suitable materials that would perform the same or a similar function as the materials described herein are intended to be embraced within the scope of the invention. Such other materials not described herein can include, but are not limited to, for example, materials that are developed after the time of the development of the invention.

Reference will now be made in detail to exemplary embodiments of the disclosed technology, examples of which are illustrated in the accompanying drawings and disclosed herein. Wherever convenient, the same references numbers will be used throughout the drawings to refer to the same or like parts.

The term “oxygen reservoir layer” is used herein to mean a layer comprising oxygen-containing material that is configured to supply oxygen ions to an adjacent ferroelectric layer during device operation. The oxygen reservoir layer may be sub-stoichiometric and contain oxygen vacancies that enable the release and migration of oxygen ions. Any layer described herein as an “oxygen reservoir layer” is not necessarily limited to a specific composition or thickness, but rather encompasses any oxygen-containing layer capable of providing oxygen ions to mitigate oxygen vacancy formation in a ferroelectric material during cycling operations.

Ferroelectric devices have emerged as promising candidates for next-generation non-volatile memory applications due to their fast switching speeds and low power consumption characteristics. These devices utilize ferroelectric materials that exhibit spontaneous electric polarization, which can be reversed by applying an external electric field. The ability to retain polarization states without continuous power supply makes ferroelectric devices suitable for various memory technologies including ferroelectric random access memory (FeRAM), ferroelectric field-effect transistors (FeFETs), and ferroelectric NAND (FE-NAND) architectures. Recent developments in ferroelectric memory technology have demonstrated performance levels comparable to dynamic random access memory (DRAM), indicating the potential for widespread adoption in computing systems.

The integration of ferroelectric memories with high-performance processors presents new challenges related to thermal management and device reliability. Modern computing architectures increasingly rely on three-dimensional stacking configurations where memory devices may be positioned directly above processing units such as graphics processing units (GPUs) or central processing units (CPUs). During intensive computational operations, these processing units generate substantial heat that transfers to the overlying memory layers. Consequently, ferroelectric memory devices may experience operating temperatures ranging from 85° C. to 145° C., which exceeds typical room temperature conditions by substantial margins. The elevated temperature environment creates additional stress conditions that can affect the long-term reliability and performance characteristics of ferroelectric devices.

One of the primary reliability challenges facing ferroelectric devices involves endurance degradation, which refers to the progressive loss of ferroelectric properties during repeated read and write operations. The endurance performance of ferroelectric devices typically decreases as operating temperature increases, limiting the practical application of these devices in thermally demanding environments. The degradation mechanism involves the formation and accumulation of defects within the ferroelectric material during cycling operations. These defects, particularly oxygen vacancies, can create conductive pathways that compromise the insulating properties of the ferroelectric layer and ultimately lead to device failure. The temperature dependence of endurance degradation becomes particularly pronounced at elevated temperatures where thermal activation accelerates defect formation processes.

Oxygen vacancy formation represents a fundamental degradation mechanism in oxide-based ferroelectric materials such as hafnium zirconium oxide (HZO). During device operation, electrical stress can break oxygen-metal bonds within the ferroelectric material, creating oxygen vacancies and releasing oxygen ions. The accumulation of oxygen vacancies over multiple cycling operations can form percolation paths that increase leakage current and degrade the ferroelectric switching characteristics. At elevated temperatures, the kinetics of oxygen vacancy formation and migration become enhanced due to increased thermal energy, leading to accelerated degradation rates. The challenge of maintaining device reliability under these conditions has motivated research into engineering approaches that can mitigate oxygen vacancy accumulation during device operation.

The concept of oxygen reservoir layers has emerged as a promising approach for addressing endurance degradation in ferroelectric devices. An oxygen reservoir layer comprises an oxygen-containing material that can supply oxygen ions to the adjacent ferroelectric layer during device operation. The fundamental principle involves providing a source of oxygen ions that can recombine with oxygen vacancies generated during cycling operations, effectively healing the damage caused by electrical stress. This self-healing mechanism can potentially extend device endurance by continuously replenishing oxygen content in the ferroelectric material. The effectiveness of oxygen reservoir layers may be enhanced at elevated temperatures where increased thermal energy facilitates oxygen ion migration and recombination processes.

The implementation of oxygen reservoir layers in ferroelectric devices involves careful consideration of material properties and interface engineering. The oxygen reservoir material should exhibit favorable oxygen ion mobility characteristics while maintaining compatibility with standard semiconductor processing techniques. The positioning of oxygen reservoir layers at strategic interfaces within the device structure can enable efficient oxygen ion transport to regions where vacancy formation occurs. Additionally, the oxygen reservoir layer should not adversely affect the ferroelectric properties of the active layer or introduce unwanted electrical characteristics such as excessive leakage current. The development of effective oxygen reservoir layer technologies requires understanding of the underlying physical mechanisms governing oxygen ion migration and vacancy formation in ferroelectric materials.

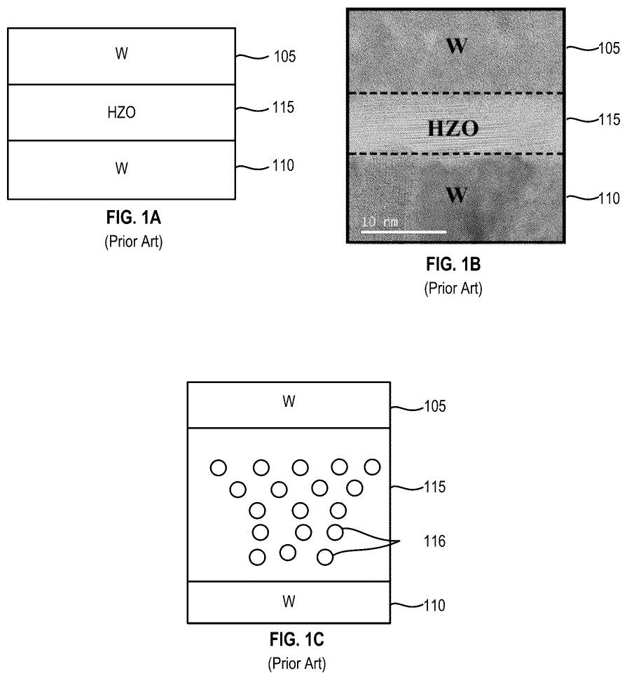

Referring to FIG. 1A, a conventional ferroelectric device structure comprises a top electrode 105, a bottom electrode 110, and a ferroelectric HZO layer 115 disposed between the top electrode 105 and the bottom electrode 110. The top electrode 105 and the bottom electrode 110 may comprise tungsten (W) or other conductive materials suitable for ferroelectric device applications. The ferroelectric HZO layer 115 comprises hafnium zirconium oxide, which exhibits ferroelectric properties that enable the storage and switching of polarization states. In some cases, the ferroelectric HZO layer 115 may have a composition of Hf_{0.5}Zr_{0.5}O₂, providing a balanced combination of hafnium and zirconium oxides that promotes ferroelectric phase formation. The device structure forms a metal-insulator-metal (MIM) capacitor configuration where the ferroelectric HZO layer 115 serves as the active dielectric material between the conductive electrodes.

As shown in FIG. 1B, the cross-sectional view of the ferroelectric device reveals the layered arrangement of the constituent materials. The ferroelectric HZO layer 115 interfaces directly with both the top electrode 105 and the bottom electrode 110, forming electrode-ferroelectric interfaces that facilitate charge injection and polarization switching during device operation. The thickness of the ferroelectric HZO layer 115 may range from approximately 5 nanometers to 10 nanometers, with thinner layers providing enhanced electric field strength for polarization switching while maintaining adequate ferroelectric properties. The electrode materials may be deposited using physical vapor deposition, chemical vapor deposition, or atomic layer deposition techniques to achieve uniform coverage and controlled thickness. The ferroelectric HZO layer 115 may be deposited using atomic layer deposition at temperatures ranging from 250° C. to 293° C., followed by post-deposition annealing to promote crystallization into the ferroelectric phase.

With continued reference to FIG. 1C, the formation of oxygen vacancies 116 within the ferroelectric HZO layer 115 represents a degradation mechanism that occurs during repeated cycling operations. The oxygen vacancies 116 are defect sites where oxygen atoms have been removed from the crystal lattice structure of the ferroelectric HZO layer 115. During electrical stress application, the energy provided by the applied electric field can break oxygen-metal bonds within the ferroelectric HZO layer 115, leading to the creation of oxygen vacancies 116 and the release of oxygen ions. The oxygen vacancies 116 may accumulate over multiple read and write cycles, progressively altering the electrical properties of the ferroelectric HZO layer 115. In some cases, the concentration of oxygen vacancies 116 may increase with the number of cycling operations, particularly under elevated temperature conditions where thermal energy enhances the kinetics of defect formation processes.

The presence of oxygen vacancies 116 in the ferroelectric HZO layer 115 can lead to several detrimental effects on device performance and reliability. The oxygen vacancies 116 may act as charge trapping sites that alter the local electric field distribution within the ferroelectric HZO layer 115, potentially affecting polarization switching characteristics. As the density of oxygen vacancies 116 increases, these defects may begin to form percolation pathways that provide conductive channels through the ferroelectric HZO layer 115. The formation of conductive pathways can result in increased leakage current between the top electrode 105 and the bottom electrode 110, compromising the insulating properties of the ferroelectric HZO layer 115. Additionally, the oxygen vacancies 116 may contribute to polarization fatigue, where the switchable polarization of the ferroelectric HZO layer 115 gradually decreases with continued cycling operations, ultimately leading to device failure when the polarization becomes insufficient for reliable memory operation.

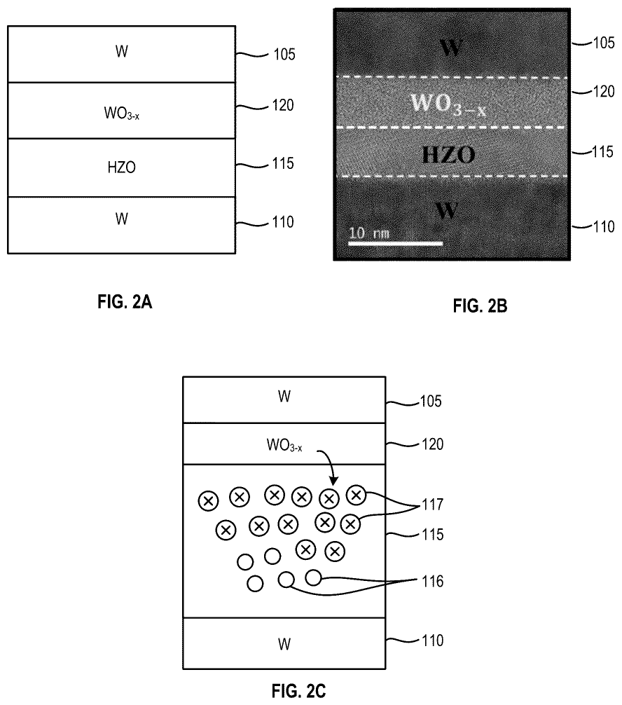

Referring to FIG. 2A, a ferroelectric device structure incorporates an upper ORL 120 positioned between the top electrode 105 and the ferroelectric HZO layer 115. The upper ORL 120 comprises an oxygen-containing material that functions as an oxygen reservoir to supply oxygen ions during device operation. The ferroelectric HZO layer 115 remains disposed between the upper ORL 120 and the bottom electrode 110, maintaining the layered configuration while introducing the oxygen reservoir functionality at the upper interface. The upper ORL 120 may comprise tungsten oxide having the formula WOₓ, where x is less than 3, providing a sub-stoichiometric composition that contains oxygen vacancies and enables oxygen ion mobility. The positioning of the upper ORL 120 at the interface between the top electrode 105 and the ferroelectric HZO layer 115 allows for direct oxygen ion transport to the ferroelectric material during cycling operations.

The upper ORL 120 may exhibit different thickness characteristics compared to other oxygen reservoir layers within the device structure. In some cases, the formation of the upper ORL 120 may involve 60 to 80 atomic layer deposition (ALD) cycles to achieve the desired thickness and oxygen content. The increased number of deposition cycles for the upper ORL 120 may provide enhanced oxygen reservoir capacity and improved oxygen ion supply characteristics during device operation. The thickness of the upper ORL 120 may range from approximately 4 nanometers to 6 nanometers, with the specific thickness determined by the number of ALD cycles and the deposition conditions employed during fabrication. The upper ORL 120 may be deposited using atomic layer deposition techniques at temperatures of approximately 250° C., utilizing tungsten precursors and oxygen-containing reactants to form the tungsten oxide composition.

As shown in FIG. 2B, the cross-sectional view of the ferroelectric device reveals the integration of the upper ORL 120 within the layered structure. The upper ORL 120 forms an interface with both the top electrode 105 and the ferroelectric HZO layer 115, creating pathways for oxygen ion migration between the reservoir layer and the ferroelectric material. The interface between the upper ORL 120 and the ferroelectric HZO layer 115 may facilitate the transport of oxygen ions from the reservoir layer to regions within the ferroelectric material where oxygen vacancies form during cycling operations. The upper ORL 120 may exhibit sub-stoichiometric characteristics with oxygen vacancy concentrations that enable the release and migration of oxygen ions under applied electric fields and thermal activation. The structural arrangement allows the upper ORL 120 to function as an active component in the oxygen ion supply mechanism while maintaining compatibility with the overall device architecture.

With continued reference to FIG. 2C, the upper ORL 120 supplies oxygen ions 117 to compensate for oxygen vacancies 116 that form within the ferroelectric HZO layer 115 during device operation. The oxygen ions 117 represent mobile oxygen species that can migrate from the upper ORL 120 into the ferroelectric HZO layer 115 under the influence of electric fields and thermal energy. During cycling operations, electrical stress may create oxygen vacancies 116 within the ferroelectric HZO layer 115 through the breaking of oxygen-metal bonds and the removal of oxygen atoms from the crystal lattice. The upper ORL 120 responds to this vacancy formation by releasing oxygen ions 117 that can migrate toward the oxygen vacancies 116 and recombine to restore the oxygen content within the ferroelectric material. The migration of oxygen ions 117 from the upper ORL 120 to the ferroelectric HZO layer 115 may be thermally activated, with increased efficiency at elevated operating temperatures where thermal energy enhances ion mobility and diffusion processes.

The oxygen ion supply mechanism facilitated by the upper ORL 120 may provide a self-healing functionality that mitigates degradation effects during repeated cycling operations. The oxygen ions 117 released from the upper ORL 120 can recombine with oxygen vacancies 116 in the ferroelectric HZO layer 115, effectively healing the damage caused by electrical stress and reducing the accumulation of defects over time. The continuous supply of oxygen ions 117 from the upper ORL 120 may help maintain the stoichiometric composition of the ferroelectric HZO layer 115 and preserve the ferroelectric properties during extended cycling operations. The effectiveness of the oxygen ion supply mechanism may be enhanced at elevated temperatures ranging from 85° C. to 145° C., where increased thermal energy facilitates oxygen ion migration and recombination kinetics. The upper ORL 120 may maintain its oxygen reservoir functionality throughout the operational lifetime of the device, providing sustained oxygen ion supply to support long-term endurance performance.

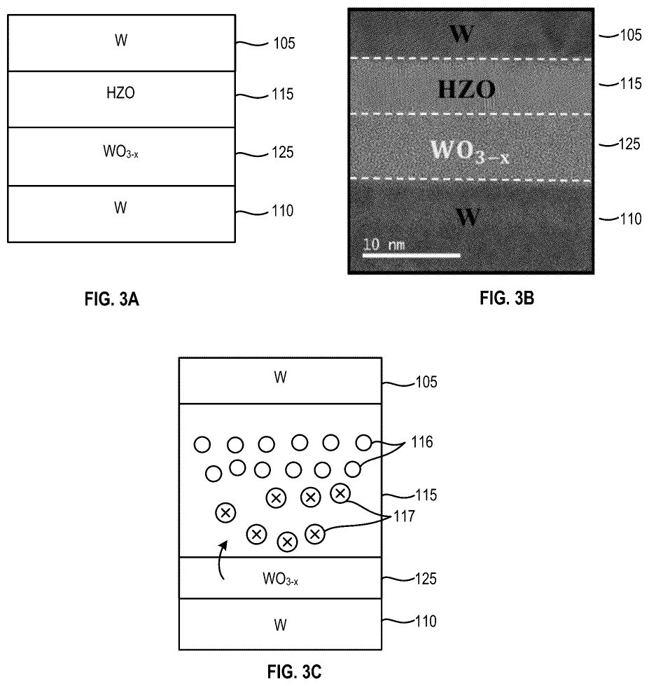

Referring to FIG. 3A, a ferroelectric device structure incorporates a lower tungsten oxide layer 125 positioned between the bottom electrode 110 and the ferroelectric HZO layer 115. The lower tungsten oxide layer 125 comprises an oxygen-containing material that functions as an oxygen reservoir to supply oxygen ions during device operation. The ferroelectric HZO layer 115 remains disposed between the top electrode 105 and the lower tungsten oxide layer 125, maintaining the layered configuration while introducing oxygen reservoir functionality at the lower interface. The lower tungsten oxide layer 125 may comprise tungsten oxide having the formula WOₓ, where x is less than 3, providing a sub-stoichiometric composition that contains oxygen vacancies and enables oxygen ion mobility. The positioning of the lower tungsten oxide layer 125 at the interface between the bottom electrode 110 and the ferroelectric HZO layer 115 allows for direct oxygen ion transport to the ferroelectric material during cycling operations.

The lower tungsten oxide layer 125 may be formed through in-situ oxidation of the bottom electrode 110 using O₂ plasma treatment in the atomic layer deposition chamber prior to ferroelectric HZO layer 115 deposition. This formation method involves depositing the bottom electrode 110 comprising tungsten, followed by exposure to oxygen plasma that oxidizes the surface region of the tungsten electrode to create the lower tungsten oxide layer 125. The in-situ oxidation process may be performed within the same deposition chamber used for subsequent layer formation, providing process integration advantages and interface control. The oxygen plasma treatment parameters may be adjusted to control the thickness and oxygen content of the lower tungsten oxide layer 125, with treatment duration and plasma power affecting the extent of tungsten oxidation. In some cases, the in-situ oxidation approach may produce a lower tungsten oxide layer 125 with approximately 28.4% oxygen vacancies, providing substantial oxygen reservoir capacity for subsequent oxygen ion supply during device operation.

As shown in FIG. 3B, the cross-sectional view of the ferroelectric device reveals the integration of the lower tungsten oxide layer 125 within the layered structure. The lower tungsten oxide layer 125 forms an interface with both the bottom electrode 110 and the ferroelectric HZO layer 115, creating pathways for oxygen ion migration between the reservoir layer and the ferroelectric material. The interface between the lower tungsten oxide layer 125 and the ferroelectric HZO layer 115 may facilitate the transport of oxygen ions from the reservoir layer to regions within the ferroelectric material where oxygen vacancies form during cycling operations. The lower tungsten oxide layer 125 may exhibit sub-stoichiometric characteristics with oxygen vacancy concentrations that enable the release and migration of oxygen ions under applied electric fields and thermal activation. The structural arrangement allows the lower tungsten oxide layer 125 to function as an active component in the oxygen ion supply mechanism while maintaining compatibility with the overall device architecture.

Alternative deposition methods may be employed for forming the lower tungsten oxide layer 125, including plasma-enhanced atomic layer deposition techniques. The plasma-enhanced ALD approach may utilize Bis(tert-butylimino)bis(dimethylamino) tungsten precursor and O₂ plasma at temperatures of approximately 250° C. to deposit the tungsten oxide material directly. This deposition method may provide enhanced control over the composition and thickness of the lower tungsten oxide layer 125 compared to in-situ oxidation approaches. The plasma-enhanced ALD process may involve alternating exposure cycles of the tungsten precursor and oxygen plasma, with each cycle contributing to the growth of the tungsten oxide layer. In some cases, the plasma-enhanced ALD method may produce a lower tungsten oxide layer 125 with approximately 21% oxygen vacancies, which differs from the oxygen vacancy concentration achieved through in-situ oxidation methods. The variation in oxygen vacancy concentration between deposition methods may affect the oxygen reservoir capacity and oxygen ion supply characteristics of the lower tungsten oxide layer 125 during device operation.

With continued reference to FIG. 3C, the lower tungsten oxide layer 125 supplies oxygen ions 117 to compensate for oxygen vacancies 116 that form within the ferroelectric HZO layer 115 during device operation. The oxygen ions 117 represent mobile oxygen species that can migrate from the lower tungsten oxide layer 125 into the ferroelectric HZO layer 115 under the influence of electric fields and thermal energy. During cycling operations, electrical stress may create oxygen vacancies 116 within the ferroelectric HZO layer 115 through the breaking of oxygen-metal bonds and the removal of oxygen atoms from the crystal lattice. The lower tungsten oxide layer 125 responds to this vacancy formation by releasing oxygen ions 117 that can migrate toward the oxygen vacancies 116 and recombine to restore the oxygen content within the ferroelectric material. The migration of oxygen ions 117 from the lower tungsten oxide layer 125 to the ferroelectric HZO layer 115 may be thermally activated, with increased efficiency at elevated operating temperatures where thermal energy enhances ion mobility and diffusion processes.

The oxygen ion supply mechanism facilitated by the lower tungsten oxide layer 125 may provide a self-healing functionality that mitigates degradation effects during repeated cycling operations. The oxygen ions 117 released from the lower tungsten oxide layer 125 can recombine with oxygen vacancies 116 in the ferroelectric HZO layer 115, effectively healing the damage caused by electrical stress and reducing the accumulation of defects over time. The continuous supply of oxygen ions 117 from the lower tungsten oxide layer 125 may help maintain the stoichiometric composition of the ferroelectric HZO layer 115 and preserve the ferroelectric properties during extended cycling operations. The effectiveness of the oxygen ion supply mechanism may be enhanced at elevated temperatures ranging from 85° C. to 145° C., where increased thermal energy facilitates oxygen ion migration and recombination kinetics. The lower tungsten oxide layer 125 may maintain its oxygen reservoir functionality throughout the operational lifetime of the device, providing sustained oxygen ion supply to support long-term endurance performance while demonstrating different oxygen vacancy concentrations depending on the specific deposition method employed during fabrication.

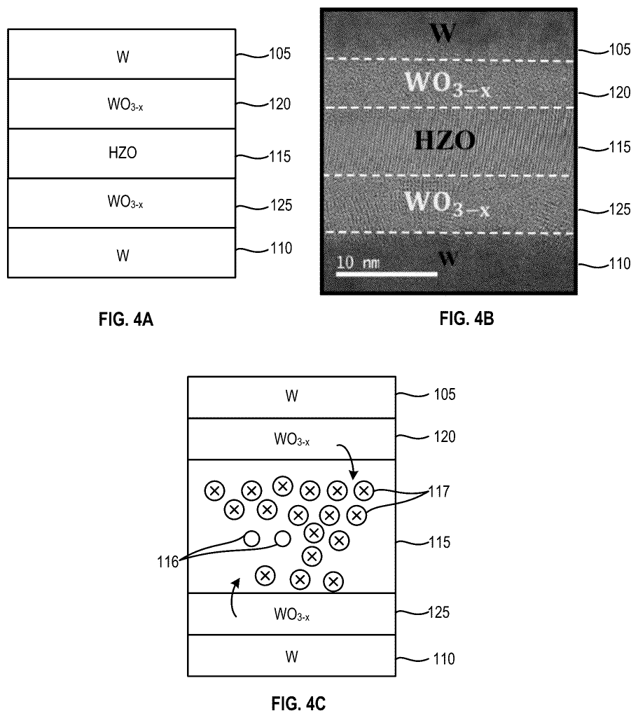

Referring to FIG. 4A, a ferroelectric device structure incorporates both an upper ORL 120 and a lower tungsten oxide layer 125 positioned at opposite interfaces of the ferroelectric HZO layer 115. The upper ORL 120 may be disposed between the top electrode 105 and the ferroelectric HZO layer 115, while the lower tungsten oxide layer 125 may be positioned between the bottom electrode 110 and the ferroelectric HZO layer 115. The ferroelectric HZO layer 115 comprising hafnium zirconium oxide remains disposed between the upper ORL 120 and the lower tungsten oxide layer 125, creating a symmetrical configuration where oxygen reservoir layers flank both interfaces of the ferroelectric material. The dual oxygen reservoir layer arrangement may provide enhanced oxygen ion supply capacity compared to single-sided configurations, with each oxygen reservoir layer comprising tungsten oxide and configured to reduce oxygen vacancy formation in the ferroelectric HZO layer 115 during cycling operations. The bottom electrode 110 comprising tungsten may serve as the foundation for the lower tungsten oxide layer 125 formation, while the top electrode 105 may interface with the upper ORL 120 to complete the layered structure.

The dual oxygen reservoir layer configuration may enable bidirectional oxygen ion supply to the ferroelectric HZO layer 115 during bipolar cycling operations. During positive voltage cycling, the electric field distribution within the device may drive oxygen ions from one oxygen reservoir layer toward regions of oxygen vacancy formation within the ferroelectric HZO layer 115. Conversely, during negative voltage cycling, the reversed electric field may facilitate oxygen ion migration from the opposite oxygen reservoir layer, providing oxygen ion supply from both interfaces depending on the applied voltage polarity. The bidirectional oxygen ion supply mechanism may provide more comprehensive coverage of oxygen vacancy healing throughout the thickness of the ferroelectric HZO layer 115 compared to unidirectional supply from a single oxygen reservoir layer. The upper ORL 120 and the lower tungsten oxide layer 125 may function cooperatively to maintain oxygen stoichiometry within the ferroelectric HZO layer 115 under various cycling conditions and voltage polarities.

As shown in FIG. 4B, the cross-sectional view of the ferroelectric capacitor reveals the integration of both oxygen reservoir layers within the layered structure. The upper ORL 120 forms an interface with both the top electrode 105 and the ferroelectric HZO layer 115, while the lower tungsten oxide layer 125 creates interfaces with the bottom electrode 110 and the ferroelectric HZO layer 115. The dual interface configuration may provide multiple pathways for oxygen ion migration between the oxygen reservoir layers and the ferroelectric material, potentially enhancing the efficiency of oxygen vacancy healing processes. The ferroelectric capacitor structure may exhibit improved thermal stability and endurance characteristics due to the enhanced oxygen ion supply capacity provided by the dual oxygen reservoir layer arrangement. The symmetrical positioning of the oxygen reservoir layers may also provide balanced oxygen ion supply characteristics that accommodate the bidirectional nature of ferroelectric polarization switching operations.

With continued reference to FIG. 4C, the dual oxygen reservoir layer configuration demonstrates the distribution of oxygen vacancies 116 and oxygen ions 117 within the ferroelectric HZO layer 115 during device operation. The oxygen ions 117 may migrate from both the upper ORL 120 and the lower tungsten oxide layer 125 toward oxygen vacancies 116 that form within the ferroelectric HZO layer 115 during cycling operations. The bidirectional oxygen ion supply may provide more uniform oxygen vacancy healing throughout the thickness of the ferroelectric HZO layer 115, potentially reducing the formation of localized regions with high oxygen vacancy concentrations. The oxygen ions 117 from the upper ORL 120 may primarily address oxygen vacancies 116 in the upper portion of the ferroelectric HZO layer 115, while oxygen ions 117 from the lower tungsten oxide layer 125 may target oxygen vacancies 116 in the lower portion of the ferroelectric material. The cooperative action of both oxygen reservoir layers may result in more effective oxygen vacancy mitigation compared to single oxygen reservoir layer configurations.

The enhanced oxygen ion supply capacity of the dual oxygen reservoir layer configuration may provide improved endurance performance under elevated temperature conditions. The upper ORL 120 and the lower tungsten oxide layer 125 may each contribute oxygen ions 117 to the ferroelectric HZO layer 115, effectively doubling the available oxygen reservoir capacity compared to single-sided configurations. The increased oxygen reservoir capacity may extend the operational lifetime of the ferroelectric device by providing sustained oxygen ion supply over extended cycling periods. The dual oxygen reservoir layer arrangement may also provide redundancy in oxygen ion supply, where the continued functionality of one oxygen reservoir layer may compensate for potential depletion or degradation of the other oxygen reservoir layer during extended device operation. The bidirectional oxygen ion supply mechanism may be particularly beneficial for ferroelectric devices operating under high-frequency cycling conditions where rapid oxygen vacancy formation and healing processes occur simultaneously.

The ferroelectric capacitor incorporating the dual oxygen reservoir layer configuration may exhibit enhanced performance characteristics across a range of operating temperatures from room temperature to elevated temperatures exceeding 125° C. The combined oxygen reservoir capacity of the upper ORL 120 and the lower tungsten oxide layer 125 may provide sufficient oxygen ion supply to maintain ferroelectric properties even under thermally accelerated degradation conditions. The bidirectional oxygen ion supply may accommodate the increased oxygen vacancy formation rates that occur at elevated temperatures, where thermal energy enhances both defect formation and oxygen ion migration processes. The dual oxygen reservoir layer configuration may also provide improved wake-up behavior and reduced polarization fatigue compared to conventional ferroelectric devices without oxygen reservoir layers. The enhanced endurance characteristics may enable the ferroelectric capacitor to meet the reliability requirements for memory applications in thermally demanding environments where conventional ferroelectric devices may experience premature failure.

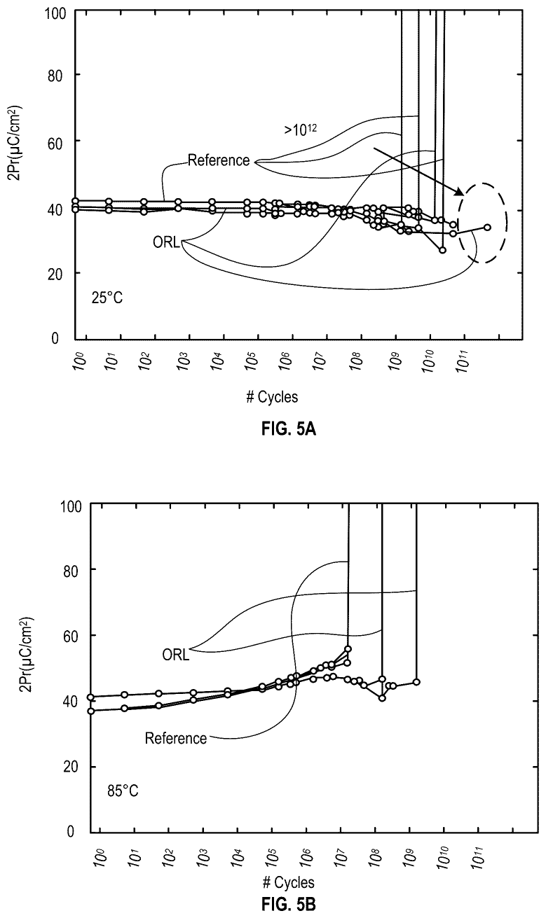

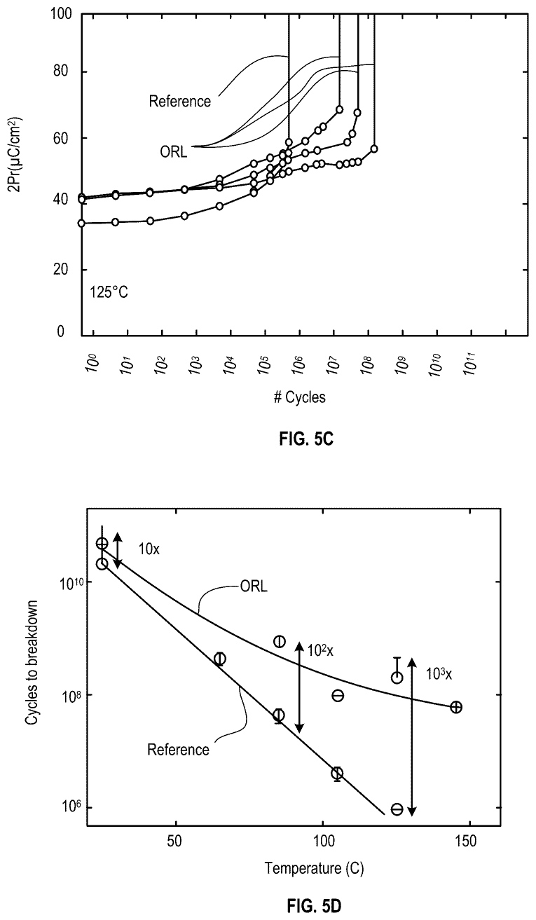

Referring to FIG. 5A, experimental data demonstrates the endurance characteristics of ferroelectric devices at room temperature conditions. The graph presents endurance data showing polarization versus cycles plotted against the number of cycling operations for both reference devices and devices incorporating oxygen reservoir layers. At 25° C. operating temperature, the oxygen reservoir layer device shows slightly better endurance than reference device, as some of the exemplary devices didn't break above 10¹¹ cycles.

The endurance data at room temperature provides baseline performance metrics for evaluating the temperature-dependent behavior of oxygen reservoir layer functionality. The reference device demonstrates a characteristic endurance behavior with continued cycling operations, reflecting the accumulation of oxygen vacancies within the ferroelectric material during repeated electrical stress application. The oxygen reservoir layer device exhibits endurance characteristics slightly better than the reference device at 25° C. The comparable endurance performance between device configurations at room temperature establish the foundation for understanding the temperature-dependent activation of oxygen ion migration processes that become apparent at elevated operating temperatures.

As shown in FIG. 5B, the endurance characteristics of ferroelectric devices at 85° C. reveal the emergence of performance differences between reference and oxygen reservoir layer configurations. The elevated temperature conditions begin to activate oxygen ion migration processes within the oxygen reservoir layer, leading to observable improvements in endurance behavior compared to room temperature operation. The oxygen reservoir layer device demonstrates improved endurance performance relative to the reference device at 85° C., indicating that thermal activation enhances the oxygen ion supply mechanism and improves the healing of cycling-induced oxygen vacancies. The temperature-dependent activation of oxygen ion migration processes becomes evident through the divergence in endurance characteristics between device configurations as operating temperature increases from room temperature to 85° C.

With continued reference to FIG. 5C, the endurance data at 125° C. demonstrates substantial performance improvements achieved through oxygen reservoir layer implementation. The elevated temperature conditions provide sufficient thermal energy to activate oxygen ion migration from the oxygen reservoir layer to the ferroelectric material, resulting in enhanced oxygen vacancy healing during cycling operations. The oxygen reservoir layer device exhibits significantly improved endurance performance compared to the reference device at 125° C., with the performance gap widening as cycling operations continue. The quantitative data reveals that the oxygen reservoir layer device maintains better endurance characteristics throughout extended cycling periods, indicating sustained oxygen ion supply and effective mitigation of degradation processes. The enhanced performance at 125° C. demonstrates that oxygen ion migration from oxygen reservoir layers becomes more efficient at elevated temperatures where thermal energy facilitates ion mobility and diffusion processes.

The temperature-dependent performance characteristics illustrated in FIGS. 5A through 5C reveal the thermally activated nature of oxygen ion migration processes within oxygen reservoir layer devices. The progression from comparable performance at 25° C. to substantial improvements at 125° C. demonstrates that elevated operating temperatures enhance the effectiveness of oxygen ion supply mechanisms. The thermal activation of oxygen ion migration processes enables oxygen reservoir layers to provide more efficient healing of cycling-induced oxygen vacancies at temperatures ranging from 85° C. to 145° C. The quantitative endurance data supports the conclusion that ferroelectric devices incorporating oxygen reservoir layers may maintain improved endurance performance under elevated temperature conditions where conventional devices experience accelerated degradation. The temperature-dependent behavior provides evidence that oxygen ion migration from oxygen reservoir layers to ferroelectric materials becomes increasingly effective as operating temperature increases within the range encountered in thermally demanding applications.

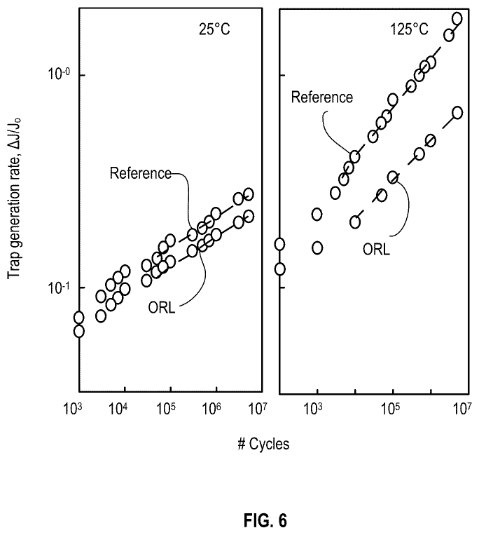

Referring to FIG. 6, comprehensive trap generation rate data demonstrates the quantitative performance improvements achieved through oxygen reservoir layer implementation across multiple temperature conditions. The graph presents trap generation rates plotted against cycling operations on a logarithmic scale, enabling comparison of device performance over extended cycling periods ranging from 10³ to 10⁷ cycles. The data reveals distinct performance characteristics between reference devices and oxygen reservoir layer devices, with the performance differences becoming more pronounced at elevated temperatures. The logarithmic presentation of cycling data allows for evaluation of long-term endurance characteristics and provides insight into the sustained effectiveness of oxygen ion supply mechanisms over extended operational periods. The quantitative metrics demonstrate that oxygen reservoir layer devices maintain lower trap generation slopes compared to reference devices, particularly under elevated temperature conditions where thermal activation enhances oxygen ion migration processes.

The trap generation rate data presented in FIG. 6 provides quantitative evidence of the endurance improvements achieved through oxygen reservoir layer implementation. The reduced trap generation slopes observed in oxygen reservoir layer devices indicate lower rates of defect accumulation during cycling operations compared to reference devices without oxygen reservoir functionality. The performance improvements become increasingly apparent at elevated temperatures, where the trap generation rate differences between device configurations widen substantially. The quantitative data demonstrates that oxygen reservoir layer devices may maintain stable trap generation characteristics over extended cycling periods, with the oxygen ion supply mechanism providing sustained healing of cycling-induced oxygen vacancies. The logarithmic scale presentation reveals that performance improvements persist across multiple decades of cycling operations, indicating the long-term effectiveness of oxygen reservoir layer functionality in maintaining device endurance characteristics.

The experimental data demonstrates that ferroelectric devices incorporating oxygen reservoir layers may operate at elevated temperatures ranging from 85° C. to 145° C. while maintaining improved endurance performance compared to conventional device configurations. The temperature-dependent activation of oxygen ion migration processes enables enhanced oxygen vacancy healing at elevated temperatures, where increased thermal energy facilitates ion mobility and diffusion within the device structure. The quantitative endurance and trap generation measurements provide evidence that oxygen ion migration from oxygen reservoir layers to ferroelectric materials becomes more efficient at elevated temperatures, resulting in reduced defect accumulation and improved device reliability. The performance data supports the implementation of oxygen reservoir layer technology in applications requiring operation under thermally demanding conditions, where conventional ferroelectric devices may experience premature degradation due to accelerated oxygen vacancy formation processes.

The ferroelectric devices described herein utilize specific material compositions that enable enhanced endurance performance through oxygen ion supply mechanisms. The ferroelectric layer comprises hafnium zirconium oxide (HZO) having a composition of Hf_{0.5}Zr_{0.5}O₂, which provides a balanced stoichiometric ratio of hafnium and zirconium oxides that promotes ferroelectric phase formation and stability. The equal molar ratio of hafnium to zirconium in the Hf_{0.5}Zr_{0.5}O₂ composition may optimize the ferroelectric properties by combining the beneficial characteristics of both hafnium oxide and zirconium oxide phases. The hafnium component may contribute to the formation of the orthorhombic ferroelectric phase, while the zirconium component may enhance the thermal stability and reduce the crystallization temperature of the ferroelectric material. The Hf_{0.5}Zr_{0.5}O₂ composition may exhibit superior ferroelectric switching characteristics compared to pure hafnium oxide or zirconium oxide compositions, making the balanced stoichiometry particularly suitable for memory device applications.

The oxygen reservoir layers comprise tungsten oxide having the formula WOₓ, where x is less than 3, indicating a sub-stoichiometric composition that deviates from the fully oxidized WO₃ stoichiometry. The sub-stoichiometric nature of the tungsten oxide material results from oxygen deficiency within the crystal structure, creating oxygen vacancies that enable oxygen ion mobility and reservoir functionality. In some cases, the value of x in the WOₓ formula may range from approximately 2.1 to 2.8, depending on the deposition conditions and post-processing treatments employed during fabrication. The sub-stoichiometric tungsten oxide composition may exhibit metallic or semiconducting electrical properties due to the presence of oxygen vacancies, which contrasts with the insulating behavior of fully stoichiometric WO₃. The oxygen vacancies within the WOₓ structure serve as sources of mobile oxygen ions that can migrate to adjacent ferroelectric layers during device operation, providing the oxygen reservoir functionality that enables self-healing of cycling-induced damage.

The oxygen vacancy concentration within tungsten oxide oxygen reservoir layers varies substantially depending on the deposition method employed during fabrication. Oxygen reservoir layers formed through O₂ plasma treatment of tungsten electrodes exhibit oxygen vacancy concentrations of approximately 28.4%, indicating a high degree of oxygen deficiency within the tungsten oxide structure. The plasma treatment process may create substantial oxygen vacancy concentrations by preferentially removing oxygen atoms from the tungsten oxide lattice through energetic ion bombardment and chemical reduction reactions. In contrast, oxygen reservoir layers deposited using atomic layer deposition techniques exhibit lower oxygen vacancy concentrations of approximately 21%, reflecting the more controlled oxidation conditions achieved through sequential precursor and oxidant exposure cycles. The difference in oxygen vacancy concentration between deposition methods may affect the oxygen reservoir capacity and oxygen ion supply characteristics of the tungsten oxide layers during device operation. The higher oxygen vacancy concentration achieved through plasma treatment may provide enhanced oxygen ion mobility and greater reservoir capacity compared to atomic layer deposition methods, potentially leading to improved self-healing performance during cycling operations.

Alternative oxygen-containing materials may serve as oxygen reservoir layers in ferroelectric devices while providing similar oxygen ion supply functionality to tungsten oxide compositions. Titanium oxide having the formula TiOₓ may function as an oxygen reservoir layer, where the sub-stoichiometric composition contains oxygen vacancies that enable oxygen ion migration to adjacent ferroelectric layers. The titanium oxide oxygen reservoir layer may exhibit different oxygen ion mobility characteristics compared to tungsten oxide, potentially affecting the temperature dependence and kinetics of oxygen ion supply processes. Niobium oxide having the formula NbOₓ represents another alternative oxygen reservoir material that may provide oxygen ion supply functionality through sub-stoichiometric compositions containing oxygen vacancies. The niobium oxide oxygen reservoir layer may offer distinct advantages in terms of chemical compatibility with specific ferroelectric materials or processing conditions. In some cases, the selection of oxygen reservoir material may depend on factors such as thermal stability, interface chemistry, and compatibility with semiconductor processing techniques. The alternative oxygen reservoir materials may exhibit varying degrees of oxygen vacancy concentration and oxygen ion mobility, allowing for tailored optimization of oxygen supply characteristics based on specific device requirements and operating conditions.

The hafnium zirconium oxide ferroelectric layer may accommodate various doping strategies and alloy compositions while maintaining compatibility with oxygen reservoir layer functionality. Doping of the HZO ferroelectric layer with elements such as aluminum, silicon, or yttrium may modify the ferroelectric properties, crystallization behavior, and thermal stability without compromising the oxygen ion supply mechanisms provided by adjacent oxygen reservoir layers. The incorporation of dopant atoms into the HZO crystal structure may alter the oxygen vacancy formation energy and migration characteristics, potentially affecting the interaction between the ferroelectric layer and oxygen reservoir layers during cycling operations. Alternative alloy compositions of hafnium and zirconium oxides may provide different ratios of hafnium to zirconium while maintaining the overall ferroelectric functionality and oxygen reservoir compatibility. In some cases, the hafnium to zirconium ratio may be adjusted to optimize specific device characteristics such as coercive field, remnant polarization, or thermal stability while preserving the ability to benefit from oxygen ion supply from adjacent oxygen reservoir layers. The flexibility in ferroelectric layer composition allows for device optimization across various applications while maintaining the fundamental oxygen reservoir functionality that enables enhanced endurance performance.

The dimensional specifications of ferroelectric device components play a role in determining device performance characteristics and manufacturing feasibility. The oxygen reservoir layer thickness may range from 4 nanometers to 6 nanometers, providing sufficient material volume to serve as an oxygen ion source while maintaining compatibility with semiconductor processing constraints. The thickness range accommodates variations in deposition conditions and process tolerances while ensuring adequate oxygen reservoir capacity for sustained oxygen ion supply during device operation. In some cases, the oxygen reservoir layer thickness may be controlled through the number of atomic layer deposition cycles employed during fabrication, with each cycle contributing incremental thickness to the growing layer. The 4 to 6 nanometer thickness range may provide a balance between oxygen reservoir functionality and overall device height considerations, where excessive thickness could increase manufacturing complexity and device footprint.

The ferroelectric layer thickness may be approximately 5 nanometers, representing a dimension that maintains ferroelectric properties while enabling efficient electric field application during polarization switching operations. The 5 nanometer thickness provides sufficient material volume to support stable ferroelectric domain formation while allowing for adequate electric field strength generation with practical operating voltages. In some cases, the ferroelectric layer thickness may be selected to optimize the coercive field characteristics and polarization switching behavior of the hafnium zirconium oxide material. The 5 nanometer dimension may represent a compromise between ferroelectric property preservation and scaling requirements for advanced memory device applications. The thickness specification may also consider the interface effects between the ferroelectric layer and adjacent oxygen reservoir layers, where thinner ferroelectric layers may exhibit enhanced interaction with oxygen ion supply mechanisms.

The hafnium zirconium oxide ferroelectric layer may accommodate thickness variations ranging from 5 nanometers up to 10 nanometers while maintaining ferroelectric functionality. The thickness range provides flexibility for device optimization based on specific application requirements and performance targets. Ferroelectric layers with thicknesses approaching 10 nanometers may exhibit enhanced polarization stability and reduced susceptibility to interface effects, while thinner layers near 5 nanometers may provide improved electric field efficiency and reduced operating voltages. In some cases, ferroelectric properties may be maintained below the 10 nanometer threshold, beyond which the material may experience degradation in ferroelectric characteristics due to structural changes or phase transitions. The thickness range allows for tailored device design where specific applications may benefit from different ferroelectric layer dimensions based on endurance requirements, operating voltage constraints, and thermal stability considerations.

The upper and lower oxygen reservoir layers may exhibit different thickness requirements based on their respective positions within the device structure and deposition sequence. The upper oxygen reservoir layer may require 60 to 80 atomic layer deposition cycles to achieve the desired thickness and oxygen content characteristics. The increased number of deposition cycles for the upper oxygen reservoir layer may compensate for differences in deposition kinetics or interface chemistry compared to the lower oxygen reservoir layer formation process. In some cases, the upper oxygen reservoir layer formation may occur after ferroelectric layer deposition, potentially affecting the deposition conditions and requiring additional cycles to achieve equivalent oxygen reservoir capacity. The 60 to 80 cycle range for the upper oxygen reservoir layer may result in thickness values within the 4 to 6 nanometer specification while providing enhanced oxygen vacancy concentration and reservoir functionality.

The lower oxygen reservoir layer may require approximately 30 atomic layer deposition cycles to achieve adequate thickness and oxygen reservoir characteristics. The reduced number of deposition cycles for the lower oxygen reservoir layer may reflect differences in deposition conditions, substrate interactions, or formation mechanisms compared to the upper oxygen reservoir layer. In some cases, the lower oxygen reservoir layer formation may benefit from direct deposition onto the bottom electrode surface, potentially providing enhanced nucleation and growth characteristics that enable effective oxygen reservoir formation with fewer deposition cycles. The 30 cycle specification for the lower oxygen reservoir layer may produce thickness values within the 4 to 6 nanometer range while achieving sufficient oxygen vacancy concentration for oxygen ion supply functionality. The position-dependent thickness requirements may reflect the asymmetric nature of the device structure and the different interface conditions encountered during sequential layer deposition processes.

The thickness specifications for oxygen reservoir layers may accommodate process variations and deposition method differences while maintaining functional performance characteristics. The 4 to 6 nanometer thickness range may encompass variations resulting from different deposition techniques, including atomic layer deposition, plasma-enhanced deposition, and in-situ oxidation methods. In some cases, the thickness range may provide tolerance for process fluctuations and equipment variations encountered in manufacturing environments. The dimensional specifications may also account for thickness measurement uncertainties and the challenges associated with characterizing nanometer-scale layer dimensions in multilayer device structures. The thickness range may ensure that oxygen reservoir layers maintain adequate oxygen ion supply capacity across the expected range of manufacturing variations while avoiding excessive thickness that could compromise device performance or integration requirements.

The fabrication of ferroelectric devices incorporating oxygen reservoir layers involves multiple deposition techniques and processing conditions that enable the formation of functional device structures with enhanced endurance characteristics. The fabrication process may begin with the deposition of a first electrode comprising tungsten or other conductive materials suitable for ferroelectric device applications. The electrode deposition may utilize physical vapor deposition, chemical vapor deposition, or atomic layer deposition techniques to achieve uniform coverage and controlled thickness across the substrate surface. The first electrode may serve as the foundation for subsequent layer formation and may provide electrical contact for device operation. In some cases, the first electrode deposition conditions may be optimized to promote adhesion and interface quality with overlying layers while maintaining the desired electrical conductivity and thermal stability characteristics.

The formation of oxygen reservoir layers may be accomplished through atomic layer deposition of tungsten oxide at temperatures of approximately 250° C. The atomic layer deposition process may involve sequential exposure of the substrate to tungsten-containing precursors and oxygen-containing reactants, with each cycle contributing to the controlled growth of the tungsten oxide layer. The deposition temperature of 250° C. may provide sufficient thermal energy to promote precursor decomposition and surface reactions while maintaining compatibility with temperature-sensitive substrate materials and previously deposited layers. The atomic layer deposition technique may enable precise thickness control and uniform coverage across complex substrate topographies, making the method suitable for nanometer-scale layer formation in ferroelectric device structures. The tungsten oxide deposited through atomic layer deposition may exhibit sub-stoichiometric characteristics with the formula WOₓ, where x is less than 3, resulting from the controlled oxygen incorporation during the deposition process.

Alternative approaches for oxygen reservoir layer formation may involve plasma-enhanced atomic layer deposition techniques utilizing Bis(tert-butylimino)bis(dimethylamino) tungsten precursor and O₂ plasma at 250° C. The plasma-enhanced deposition method may provide enhanced reactivity and improved film quality compared to thermal atomic layer deposition approaches. The O₂ plasma may serve as an oxidizing agent that promotes the formation of tungsten oxide while providing additional energy for surface reactions and film densification. The Bis(tert-butylimino)bis(dimethylamino) tungsten precursor may offer favorable volatility and reactivity characteristics that enable uniform tungsten delivery to the substrate surface during the deposition process. The plasma-enhanced atomic layer deposition technique may result in tungsten oxide layers with different oxygen vacancy concentrations compared to thermal deposition methods, potentially affecting the oxygen reservoir capacity and oxygen ion supply characteristics of the resulting layers.

The formation of oxygen reservoir layers may also be achieved through in-situ oxidation of tungsten electrodes using O₂ plasma treatment within the atomic layer deposition chamber prior to ferroelectric layer deposition. The in-situ oxidation approach may involve depositing tungsten as the first electrode followed by exposure to oxygen plasma that oxidizes the surface region of the tungsten material to create the oxygen reservoir layer. The plasma treatment parameters, including plasma power, exposure duration, and chamber pressure, may be adjusted to control the extent of tungsten oxidation and the resulting thickness of the oxygen reservoir layer. The in-situ oxidation method may provide process integration advantages by enabling oxygen reservoir layer formation within the same deposition chamber used for subsequent layer formation, reducing contamination risks and improving interface quality. The oxygen plasma treatment may create substantial oxygen vacancy concentrations within the tungsten oxide layer, providing enhanced oxygen reservoir capacity for subsequent oxygen ion supply during device operation.

The deposition of ferroelectric layers comprising hafnium-based oxides may be accomplished through thermal atomic layer deposition at temperatures ranging from 250° C. to 293° C. The thermal atomic layer deposition process may utilize hafnium and zirconium precursors along with water vapor as the oxidizing agent to form hafnium zirconium oxide layers with controlled composition and thickness. The deposition temperature range may be selected to provide adequate precursor reactivity while maintaining compatibility with temperature-sensitive substrate materials and previously deposited oxygen reservoir layers. The thermal atomic layer deposition technique may enable precise control over the hafnium to zirconium ratio within the ferroelectric layer, allowing for composition optimization based on specific device requirements. The sequential precursor exposure cycles may result in uniform layer formation with excellent conformality across substrate features and interfaces with underlying oxygen reservoir layers.

Plasma-enhanced atomic layer deposition techniques may be employed for ferroelectric layer formation using O₂ plasma as the oxidant, providing wake-up-free behavior and enhanced thermal stability compared to thermal atomic layer deposition with water vapor. The plasma-enhanced deposition method may utilize O₂ plasma to provide oxygen species with enhanced reactivity compared to water vapor, potentially resulting in improved film quality and reduced defect concentrations within the ferroelectric layer. The wake-up-free behavior achieved through plasma-enhanced deposition may eliminate the need for initial cycling operations to activate ferroelectric properties, providing immediate device functionality upon fabrication completion. The enhanced thermal stability characteristics of plasma-enhanced deposited ferroelectric layers may improve device reliability under elevated temperature operating conditions where thermal stress may affect ferroelectric properties. The O₂ plasma oxidant may also provide better control over oxygen incorporation within the ferroelectric layer, potentially reducing oxygen vacancy concentrations and improving the interaction with adjacent oxygen reservoir layers.

The crystallization of ferroelectric layers may be achieved through post-deposition annealing at 550° C. for 60 seconds to 1 minute in nitrogen ambient conditions. The annealing process may promote the transformation of the as-deposited amorphous or poorly crystallized hafnium zirconium oxide into the ferroelectric orthorhombic phase that exhibits polarization switching characteristics. The annealing temperature of 550° C. may provide sufficient thermal energy to drive crystallization processes while avoiding excessive grain growth or phase decomposition that could degrade ferroelectric properties. The annealing duration of 60 seconds to 1 minute may represent an optimized time range that achieves complete crystallization while minimizing thermal budget and potential damage to temperature-sensitive device components. The nitrogen ambient atmosphere during annealing may prevent oxidation or reduction reactions that could alter the composition or properties of the ferroelectric layer and adjacent oxygen reservoir layers.

The nitrogen ambient annealing conditions may also provide protection against contamination and unwanted chemical reactions during the high-temperature crystallization process. The inert nitrogen atmosphere may prevent the incorporation of impurities from the annealing environment while maintaining the desired oxygen content within the ferroelectric layer and oxygen reservoir layers. The controlled annealing environment may preserve the oxygen vacancy concentrations within oxygen reservoir layers that enable oxygen ion supply functionality during subsequent device operation. In some cases, the annealing process may be performed using rapid thermal processing equipment that provides precise temperature control and uniform heating across the substrate surface. The crystallization annealing may represent a final processing step that activates ferroelectric properties while preserving the oxygen reservoir functionality of adjacent tungsten oxide layers.

The fabrication sequence may involve careful coordination of deposition and processing conditions to maintain the integrity and functionality of each layer within the device structure. The temperature compatibility between different processing steps may be considered to prevent degradation of previously deposited layers during subsequent fabrication operations. The interface quality between oxygen reservoir layers and ferroelectric layers may be preserved through controlled processing conditions that minimize interdiffusion or chemical reactions that could compromise oxygen ion supply mechanisms. The overall fabrication process may be designed to achieve the desired device performance characteristics while maintaining compatibility with semiconductor manufacturing equipment and processes. The resulting ferroelectric devices may exhibit enhanced endurance performance due to the oxygen reservoir functionality enabled by the specific fabrication techniques and processing conditions employed during device formation.

The operational characteristics of ferroelectric devices incorporating oxygen reservoir layers involve complex physical mechanisms that enable enhanced endurance performance through self-healing functionality. During device operation, ferroelectric devices comprising a first electrode, a second electrode, and a ferroelectric layer disposed between the first electrode and the second electrode experience electrical stress that may create oxygen vacancies within the ferroelectric layer comprising a hafnium-based oxide. The oxygen reservoir layer disposed at an interface between one of the first electrode or the second electrode and the ferroelectric layer responds to this vacancy formation through oxygen ion migration processes that provide compensatory oxygen supply to the ferroelectric material. The self-healing mechanism operates through the migration of oxygen ions from the oxygen reservoir layer to regions within the ferroelectric layer where oxygen vacancies form during cycling operations, effectively restoring the stoichiometric composition and mitigating degradation effects.

The oxygen reservoir layer configured to supply oxygen ions to the ferroelectric layer during operation of the ferroelectric device exhibits asymmetric diffusion characteristics that favor oxygen ion migration from the reservoir layer to the ferroelectric material. The energy barrier for oxygen ion migration from tungsten oxide to hafnium zirconium oxide may be approximately 1.8 electron volts, representing a relatively low activation energy that facilitates oxygen ion transport under applied electric fields and thermal conditions. In contrast, the reverse migration pathway from hafnium zirconium oxide to tungsten oxide may exhibit a substantially higher energy barrier of approximately 4.0 electron volts, creating an asymmetric diffusion profile that promotes unidirectional oxygen ion flow from the oxygen reservoir layer to the ferroelectric layer. The asymmetric diffusion barriers ensure that oxygen ions supplied to the ferroelectric layer during cycling operations remain within the ferroelectric material rather than returning to the oxygen reservoir layer, maximizing the effectiveness of the self-healing mechanism.

The thermally activated nature of oxygen ion migration processes becomes apparent at elevated operating temperatures where increased thermal energy enhances ion mobility and diffusion kinetics within the device structure. At temperatures ranging from 85° C. to 145° C., the thermal energy may provide sufficient activation to overcome the 1.8 electron volt energy barrier for oxygen ion migration from tungsten oxide to hafnium zirconium oxide, resulting in enhanced oxygen ion supply rates compared to room temperature operation. The elevated temperature conditions may accelerate both the formation of oxygen vacancies within the ferroelectric layer and the migration of compensatory oxygen ions from the oxygen reservoir layer, creating a dynamic equilibrium where self-healing processes counteract cycling-induced degradation. The temperature dependence of oxygen ion migration may explain the enhanced endurance performance observed in oxygen reservoir layer devices at elevated temperatures, where thermal activation enables more efficient oxygen vacancy healing compared to room temperature conditions.

The self-healing functionality demonstrates particular effectiveness under elevated temperature conditions where ferroelectric devices may operate in thermally demanding applications such as memory systems integrated with high-performance processors. The combination of increased oxygen vacancy formation rates and enhanced oxygen ion migration kinetics at elevated temperatures may create optimal conditions for self-healing processes that maintain ferroelectric properties during extended cycling operations. The oxygen ions supplied from the oxygen reservoir layer may recombine with cycling-induced oxygen vacancies through thermally activated processes that restore oxygen-metal bonds within the ferroelectric layer crystal structure. The recombination reactions may occur preferentially at elevated temperatures where thermal energy facilitates the formation of stable oxygen-metal bonds and promotes the healing of lattice defects created during electrical stress application.

The operational mechanism involves continuous oxygen ion supply from the oxygen reservoir layer throughout the device lifetime, providing sustained self-healing capability that adapts to varying levels of cycling-induced damage. During periods of intensive cycling operations, increased oxygen vacancy formation within the ferroelectric layer may trigger enhanced oxygen ion migration from the oxygen reservoir layer, creating a responsive healing mechanism that scales with the level of applied stress. The asymmetric diffusion characteristics ensure that oxygen ions migrate preferentially toward regions of high oxygen vacancy concentration within the ferroelectric layer, providing targeted healing of the most severely degraded areas. The thermally activated migration processes may become more efficient as operating temperature increases, enabling ferroelectric devices to maintain improved endurance performance even under accelerated degradation conditions encountered at elevated temperatures.

The self-healing mechanism may operate continuously during device operation, providing real-time mitigation of cycling-induced damage without requiring external intervention or specialized operating procedures. The oxygen ion migration processes may occur simultaneously with normal device operation, including polarization switching and charge storage functions, without interfering with the ferroelectric properties or electrical characteristics of the device. The continuous nature of the self-healing mechanism may prevent the accumulation of oxygen vacancies that would otherwise lead to progressive degradation and eventual device failure. The effectiveness of the self-healing functionality may increase with operating temperature, providing enhanced protection against degradation in applications where ferroelectric devices experience elevated thermal conditions during normal operation.

The oxygen reservoir layer technology described herein may be implemented across various ferroelectric device architectures beyond the capacitor configurations previously discussed. The fundamental principle of oxygen ion supply to mitigate cycling-induced degradation remains applicable to different device structures while accommodating the specific geometric and operational requirements of each architecture. The self-healing functionality enabled by oxygen reservoir layers may provide endurance improvements across multiple ferroelectric device types, expanding the potential applications for enhanced reliability ferroelectric memory technologies. The versatility of oxygen reservoir layer implementation allows for adaptation to diverse device architectures while maintaining the core oxygen ion supply mechanisms that enable degradation mitigation during cycling operations.

Ferroelectric field-effect transistors represent an alternative device architecture that may incorporate oxygen reservoir layers to enhance endurance performance and reliability characteristics. The ferroelectric field-effect transistor structure may comprise a semiconductor channel region, source and drain electrodes, and a gate stack that includes a ferroelectric layer for polarization-based charge control. The ferroelectric layer within the gate stack may comprise hafnium zirconium oxide or other hafnium-based oxide materials that exhibit ferroelectric properties suitable for transistor operation. An oxygen reservoir layer may be positioned at an interface between the ferroelectric layer and adjacent conductive layers within the gate stack, providing oxygen ion supply functionality during transistor switching operations. The oxygen reservoir layer may comprise tungsten oxide having the formula WOₓ, where x is less than 3, maintaining the sub-stoichiometric composition that enables oxygen ion mobility and reservoir functionality.

The integration of oxygen reservoir layers within ferroelectric field-effect transistor structures may address specific degradation mechanisms that occur during repeated programming and erasing operations. During transistor operation, the ferroelectric layer experiences electrical stress from gate voltage application, which may create oxygen vacancies within the ferroelectric material through bond-breaking processes similar to those observed in capacitor structures. The oxygen reservoir layer positioned within the gate stack may supply oxygen ions to compensate for these cycling-induced oxygen vacancies, maintaining the ferroelectric properties and preventing the formation of conductive pathways that could compromise transistor performance. The self-healing mechanism may operate continuously during transistor switching operations, providing real-time mitigation of degradation effects without interfering with normal device functionality.

The ferroelectric field-effect transistor architecture may accommodate oxygen reservoir layers at multiple interfaces within the gate stack structure, depending on the specific layer arrangement and processing requirements. In some cases, an oxygen reservoir layer may be positioned between the ferroelectric layer and a metal gate electrode, providing oxygen ion supply from the gate side of the ferroelectric material. Alternative configurations may include oxygen reservoir layers positioned between the ferroelectric layer and underlying interface layers or buffer layers within the gate stack. The positioning of oxygen reservoir layers within the ferroelectric field-effect transistor structure may be optimized based on the electric field distribution during transistor operation and the regions where oxygen vacancy formation occurs most frequently during cycling operations.

The operational characteristics of ferroelectric field-effect transistors incorporating oxygen reservoir layers may exhibit enhanced endurance performance compared to conventional ferroelectric transistor structures without oxygen reservoir functionality. The oxygen ion supply mechanism may maintain the ferroelectric switching characteristics of the gate stack over extended programming and erasing cycles, preventing the gradual degradation of threshold voltage control and channel conductance modulation. The self-healing functionality may become particularly beneficial in ferroelectric field-effect transistor applications where high-frequency switching operations create intensive cycling conditions that accelerate oxygen vacancy formation within the ferroelectric layer. The temperature-dependent activation of oxygen ion migration processes may provide enhanced protection against degradation in ferroelectric field-effect transistor applications operating under elevated temperature conditions.

NAND-type ferroelectric memory structures represent another device architecture that may benefit from oxygen reservoir layer implementation for enhanced endurance and reliability performance. The NAND-type architecture may comprise arrays of ferroelectric memory cells arranged in series-connected strings, where each memory cell includes a ferroelectric layer that stores information through polarization states. The ferroelectric layers within NAND-type structures may experience cycling stress during program, erase, and read operations, creating conditions that promote oxygen vacancy formation and potential degradation of ferroelectric properties. Oxygen reservoir layers may be incorporated at interfaces within the NAND-type memory cell structure to provide oxygen ion supply that mitigates cycling-induced degradation and maintains memory cell functionality over extended operational periods.

The NAND-type ferroelectric memory architecture may accommodate oxygen reservoir layers at various positions within the memory cell structure, depending on the specific cell design and layer arrangement. In some cases, oxygen reservoir layers may be positioned between ferroelectric storage layers and adjacent conductive layers such as word lines or bit lines that provide electrical access to individual memory cells. The oxygen reservoir layers may comprise tungsten oxide or alternative oxygen-containing materials that exhibit sub-stoichiometric compositions with oxygen vacancy concentrations suitable for oxygen ion supply functionality. The positioning and composition of oxygen reservoir layers within NAND-type structures may be optimized to provide effective oxygen ion supply while maintaining compatibility with the high-density array architecture and manufacturing processes employed in NAND memory fabrication.

The operational benefits of oxygen reservoir layer implementation in NAND-type ferroelectric memory structures may include enhanced program/erase endurance, improved data retention characteristics, and reduced susceptibility to cycling-induced degradation effects. The oxygen ion supply mechanism may maintain the ferroelectric switching properties of individual memory cells throughout extended cycling operations, preventing the gradual loss of polarization switching capability that could lead to memory cell failure. The self-healing functionality may operate across multiple memory cells within the NAND array, providing distributed degradation mitigation that enhances the overall reliability of the memory system. The temperature-dependent activation of oxygen ion migration processes may provide additional protection against degradation in NAND-type ferroelectric memory applications operating under elevated temperature conditions encountered in high-performance computing environments.

The scalability of oxygen reservoir layer technology across different ferroelectric device architectures may enable widespread adoption of enhanced endurance ferroelectric memory technologies in various applications. The fundamental oxygen ion supply mechanisms remain applicable regardless of the specific device geometry or operational characteristics, allowing for consistent degradation mitigation across diverse ferroelectric device types. The manufacturing processes for oxygen reservoir layer formation may be adapted to accommodate the specific requirements of different device architectures while maintaining the core functionality that enables self-healing performance. The versatility of oxygen reservoir layer implementation may facilitate the development of ferroelectric memory technologies that meet the reliability requirements of demanding applications across multiple device architectures and operational environments.

The integration of oxygen reservoir layers across various ferroelectric device architectures may provide system-level benefits in applications where multiple device types operate within the same thermal and electrical environment. The consistent endurance enhancement provided by oxygen reservoir layers may enable the development of heterogeneous ferroelectric memory systems that combine different device architectures while maintaining uniform reliability characteristics. The temperature-dependent activation of oxygen ion migration processes may provide coordinated degradation mitigation across different device types operating under similar thermal conditions. The implementation of oxygen reservoir layer technology across multiple ferroelectric device architectures may contribute to the advancement of ferroelectric memory technologies as viable alternatives to conventional memory systems in applications requiring enhanced endurance and thermal stability.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

1. A ferroelectric device, comprising:
a first electrode;
a second electrode;
a ferroelectric layer disposed between the first electrode and the second electrode, the ferroelectric layer comprising a hafnium-based oxide; and
an oxygen reservoir layer disposed at an interface between one of the first electrode or the second electrode and the ferroelectric layer, the oxygen reservoir layer configured to supply oxygen ions to the ferroelectric layer during operation of the ferroelectric device.

2. The ferroelectric device of claim 1, wherein the hafnium-based oxide comprises hafnium zirconium oxide (HZO).

3. The ferroelectric device of claim 2, wherein the oxygen reservoir layer comprises tungsten and oxygen and hafnium zirconium oxide has a composition of Hf0.5Zr0.5O2.

4. The ferroelectric device of claim 1, wherein the oxygen reservoir layer has a thickness in a range of 4 nanometers to 6 nanometers.

5. The ferroelectric device of claim 1, wherein the ferroelectric layer has a thickness of about 5 nanometers.

6. The ferroelectric device of claim 1, wherein the oxygen reservoir layer comprises tungsten oxide having the formula WOx, where x is less than 3.

7. The ferroelectric device of claim 6, wherein the oxygen reservoir layer is sub-stoichiometric and comprises oxygen vacancies.

8. The ferroelectric device of claim 1, wherein the oxygen reservoir layer is disposed at an interface between the first electrode and the ferroelectric layer.

9. The ferroelectric device of claim 8, further comprising a second oxygen reservoir layer disposed at an interface between the second electrode and the ferroelectric layer.

10. The ferroelectric device of claim 9, wherein the oxygen reservoir layer and the second oxygen reservoir layer are configured to provide bidirectional oxygen ion supply to the ferroelectric layer during bipolar cycling operation.

11. A method of fabricating a ferroelectric device, comprising:
depositing a first electrode;
depositing an oxygen reservoir layer on the first electrode;
depositing a ferroelectric layer comprising a hafnium-based oxide on the oxygen reservoir layer; and
depositing a second electrode on the ferroelectric layer,
wherein the oxygen reservoir layer is configured to supply oxygen ions to the ferroelectric layer during operation of the ferroelectric device.

12. The method of claim 11, wherein depositing the oxygen reservoir layer comprises depositing tungsten oxide having the formula WOx, where x is less than 3.

13. The method of claim 11, wherein depositing the oxygen reservoir layer comprises:
depositing tungsten as the first electrode; and
applying oxygen plasma to the tungsten to form the oxygen reservoir layer.

14. The method of claim 11, wherein depositing the oxygen reservoir layer comprises atomic layer deposition of tungsten oxide.

15. The method of claim 14, wherein the atomic layer deposition is performed at a temperature of about 250°C.

16. A ferroelectric capacitor, comprising:
a bottom electrode comprising tungsten;
a top electrode;
a ferroelectric layer disposed between the bottom electrode and the top electrode, the ferroelectric layer comprising hafnium zirconium oxide;
a first oxygen reservoir layer disposed between the bottom electrode and the ferroelectric layer; and
a second oxygen reservoir layer disposed between the ferroelectric layer and the top electrode, wherein each of the first oxygen reservoir layer and the second oxygen reservoir layer comprises tungsten oxide and is configured to reduce oxygen vacancy formation in the ferroelectric layer during cycling operations.

17. The ferroelectric capacitor of claim 16, wherein the hafnium zirconium oxide has a composition of Hf0.5Zr0.5O2.

18. The ferroelectric capacitor of claim 16, wherein each of the first oxygen reservoir layer and the second oxygen reservoir layer has a thickness in a range of 4 nanometers to 6 nanometers.

19. The ferroelectric capacitor of claim 18, wherein the ferroelectric layer has a thickness of about 5 nanometers.

20. The ferroelectric capacitor of claim 16, wherein each of the first oxygen reservoir layer and the second oxygen reservoir layer comprises tungsten oxide having the formula WOx, where x is less than 3, and wherein the tungsten oxide is sub-stoichiometric and comprises oxygen vacancies.
